(19) United States
(12) Patent Application Publication
(10) Pub. No.: US 2024/0282813 A1
(43) Pub. Date: Aug. 22, 2024

(54) SILICON SUPER JUNCTION STRUCTURES FOR INCREASED THROUGHPUT

(71) Applicant: Applied Materials, Inc., Santa Clara, CA (US)

(72) Inventors: Amirhasan Nourbakhsh, Albany, NY (US); Raman Gaire, Mechanicville, NY (US); Roger Quon, Rhinebeck, NY (US); Siddarth Krishnan, San Jose, CA (US)

(73) Assignee: Applied Materials, Inc., Santa Clara, CA (US)

(21) Appl. No.: 18/171,119

(22) Filed: Feb. 17, 2023

(51) Int. Cl. H01L 29/06; H01L 21/02; H01L 21/3065; H01L 29/66; H01L 29/78

(52) U.S. Cl. CPC H01L 29/0634; H01L 21/02532; H01L 21/02576; H01L 21/02579; H01L 21/0262; H01L 21/3065; H01L 29/0649; H01L 29/66712; H01L 29/7802

(57) ABSTRACT

A super junction device with an increased manufacturing throughput may be formed by forming narrow trenches lined with a P-type liner and rapidly filled with a passive fill material. Instead of etching trenches with aspect ratio large enough to reliably fill with doped P-type material, the aspect ratio of the trench may be reduced to shrink the size of the device. This smaller trench may then be lined with a relatively thin (e.g., about 1 μm to about 2 μm) P-type liner instead of completely filling the trench with P-type material. Inside the P-type liner, the trench may then be filled with a passive fill material. Filling the trench with the passive fill material may be carried out in a matter of minutes at relatively high temperatures, thereby likely causing a void or seam to form within the passive fill material. However, because the passive fill material does not affect the operation of the device, this type of defect can exist in the device.

### TECHNICAL FIELD

The present technology relates to semiconductor systems, processes, and equipment. More specifically, the present technology relates to processes and systems to improve scaling for high aspect ratio power devices.

### BACKGROUND

Integrated circuits are made possible by processes which produce intricately patterned material layers on substrate surfaces. Producing patterned material on a substrate requires controlled methods for forming and removing material. As device sizes continue to reduce, features within the integrated circuits may get smaller and aspect ratios of structures may grow, and maintaining dimensions of these structures during processing operations may be challenged. Some processing may result in recessed features in the materials that may have uneven, or tapered, sidewalls due to increased exposure during processing. Developing materials with straight sidewalls may become more difficult. Further, backfilling recessed features with material without any seams and/or voids may also become more difficult.

Thus, there is a need for improved systems and methods that can be used to produce high quality devices and structures. These and other needs are addressed by the present technology.

### SUMMARY

In some embodiments, a super junction device may include a first N-type region extending orthogonally up from a substrate. The substrate may form a first contact region for the device. The device may also include a second N-type region extending orthogonally up from the substrate to a second contact region of the device. The device may further include a trench between the first N-type region and the second N-type region. The trench may be lined with a P-type liner along sidewalls of the trench. The P-type liner may contact a third contact region of the device. The trench may be filled with a passive fill material between the P-type liner.

In some embodiments, a super junction device may include a silicon substrate forming a drain region for the device, a gate region, a source region, an N-type region extending from the silicon substrate up to the gate region, a P-type region extending from the silicon substrate up to the source region, and a passive fill material extending up to the source region. The P-type region may be between the passive fill material and the N-type region. The passive fill material may include a void or seam inside the passive fill material.

In some embodiments, a method of forming a super junction device may include forming an N-type material on a substrate, and etching a trench in the N-type material. The trench may extend from a top surface of the N-type material down to at least a top surface of the substrate to form a first N-type region and a second N-type region. The method may also include forming a P-type liner in the trench, and filling the trench with a passive fill material.

In any embodiments, any and all of the following features may be implemented in any combination and without limitation. A height of the P-type liner may be greater than or about 40 μm. A width of the P-type liner may be less than or about 200 nm. The first contact region may include a drain of a super junction transistor, the second contact region may include a gate of the super junction transistor, and the third contact region may include a source of the super junction transistor. The super junction transistor may have a breakdown voltage of greater than or about 650 V. A width of the trench may be less than or about 2 μm. A doping concentration of the P-type liner may be higher than a doping concentration of the second N-type region. The void or seam may be a least 1 μm from a bottom of the passive fill material, and the void or seam may be at least 1 μm from a top of the passive fill material. An aspect ratio of an area occupied by the P-type region and the passive fill material may be greater than or about 20. An aspect ratio of an area occupied by the P-type region and the passive fill material may be greater than or about 40. The trench may be filled with the passive fill material in less than 15 minutes. The trench may be filled with the passive fill material without one or more grow-etch cycles. The passive fill material may include undoped silicon. The trench may be filled with the passive fill material at a temperature greater than or about 900° C. The method may also include planarizing a top surface of the device after filling the trench with the passive fill material to remove excess passive fill material. The trench may be etched below the top surface of the substrate. The P-type liner may be grown on sidewalls of the trench as a P-doped epitaxial silicon liner. A doping concentration of the N-type material may be between about 1e14 dopants/cm³ and about 1e16 dopants/cm³, and a doping concentration of the P-type liner may be greater than about 8 times the doping concentration of the N-type material.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

FIG. 1 shows a top plan view of one embodiment of a processing system of deposition, etching, baking, and curing chambers that may be included or configured according to some embodiments of the present technology.

FIG. 2 illustrates a super junction device, according to some embodiments.

FIG. 3 illustrates a flowchart of a method of forming a super junction device that allows for a reduced pitch and faster trench fill, according to some embodiments.

FIGS. 4A-4E illustrate incremental structures for forming the super junction device, according to some embodiments.

### DETAILED DESCRIPTION

A super junction device with an increased manufacturing throughput may be formed by forming narrow trenches lined with a P-type liner and rapidly filled with a passive fill material. Instead of etching trenches with aspect ratio large enough to reliably fill with doped P-type material, the aspect ratio of the trench may be reduced to shrink the size of the device. This smaller trench may then be lined with a relatively thin (e.g., about 1 μm to about 2 μm) P-type liner instead of completely filling the trench with P-type material. Inside the P-type liner, the trench may then be filled with a passive fill material. Filling the trench with the passive fill material may be carried out in a matter of minutes at relatively high temperatures, thereby likely causing a void or seam to form within the passive fill material. However, because the passive fill material does not affect the operation of the device, this type of defect can exist in the device.

As device sizes continue to shrink, many material layers may be reduced in thickness and size to scale devices. Features inside semiconductor structures may be reduced in size, and aspect ratios of the features may increase. As the aspect ratios of the features increase, patterning operations may struggle to uniformly etch features without tapering the sidewalls of the feature, or compromising feature dimensions or integrity, due to increased exposure nearer a surface of the substrate material being processed. Further, refilling a feature with higher aspect ratios may be increasingly difficult due to pinch off at the top of the feature that prevents the feature from being filled without seams and/or voids.

In forming power device structures, conventional technologies have been limited in device scaling for increased aspect ratio features based on the natural effects of prolonged etching and deposition operations. For example, in super junction structures, p-type silicon pillars are formed by filling trenches etched into n-type silicon with p-type material. In these structures, the on-resistance is controlled by the pitch or width of the different materials. The resistance may be improved by reducing the width of the p-type silicon pillars. Scaling the p-type silicon pillars is limited by etching and seam and/or void free trench filling capabilities. For example, increasing the aspect ratio with conventional etching may cause pitch degradation and tapered features due to the prolonged exposure of upper regions of the feature being formed. Additionally, the fill operation of high-aspect ratio features may lead to pinch off before deeper regions of the feature are filled. Consequently, conventional technologies have been limited to lower aspect ratios, or shorter structures to limit performance effects or device failure. Accordingly, many conventional technologies have been limited in the ability to prevent structural flaws in the final devices or improve on historical designs.

The present technology overcomes these issues by redefining the way in which the pillars are formed in the base material. By forming a thin epitaxial liner smaller feature prior to backfill, the pillars of material can be maintained at much smaller widths compared to conventional technologies. More specifically, the width of the pillars of material may be defined by the width of the epitaxial liner rather than the width of the recessed features. Additionally, the recessed features can be made smaller than conventional technologies and rapidly backfilled with a passive fill material, since voids or seams in the passive fill material do not affect the operation of the device. By changing the formation process itself, the present technology may afford much greater aspect ratio features, and also may greatly increase the throughput when manufacturing multiple devices.

Although the remaining disclosure will routinely identify specific etching and deposition processes utilizing the disclosed technology, it will be readily understood that the systems and methods are equally applicable to a variety of other processes as may occur in the described chambers. Accordingly, the technology should not be considered to be so limited as for use with the described etching or deposition processes alone. The disclosure will discuss one possible system that can be used with the present technology before describing systems and methods or operations of exemplary process sequences according to some embodiments of the present technology. It is to be understood that the technology is not limited to the equipment described, and processes discussed may be performed in any number of processing chambers and systems.

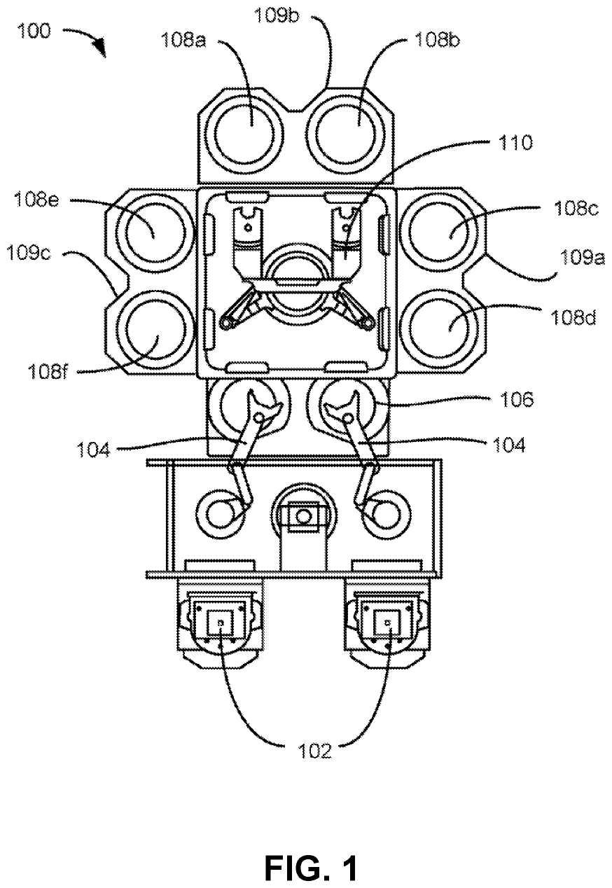

FIG. 1 shows a top plan view of one embodiment of a processing system 100 of deposition, etching, baking, and curing chambers that may be included or configured according to some embodiments of the present technology. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including the dry etch processes described herein in addition to cyclical layer deposition, atomic layer deposition, chemical vapor deposition, physical vapor deposition, etch, pre-clean, anneal, plasma processing, degas, orientation, and other substrate processes.

The substrate processing chambers 108a-f may include one or more system components for depositing, annealing, curing and/or etching a material film on the substrate or wafer. In one configuration, two pairs of the processing chambers, for example 108c-d and 108e-f, may be used to deposit material on the substrate, and the third pair of processing chambers, for example 108a-b, may be used to cure, anneal, or treat the deposited films. In another configuration, all three pairs of chambers, for example 108a-f, may be configured to both deposit and cure a film on the substrate. Any one or more of the processes described may be carried out in additional chambers separated from the fabrication system shown in different embodiments. It will be appreciated that additional configurations of deposition, etching, annealing, and curing chambers for material films are contemplated by system 100. Additionally, any number of other processing systems may be utilized with the present technology, which may incorporate chambers for performing any of the specific operations. In some embodiments, chamber systems which may provide access to multiple processing chambers while maintaining a vacuum environment in various sections, such as the noted holding and transfer areas, may allow operations to be performed in multiple chambers while maintaining a particular vacuum environment between discrete processes.

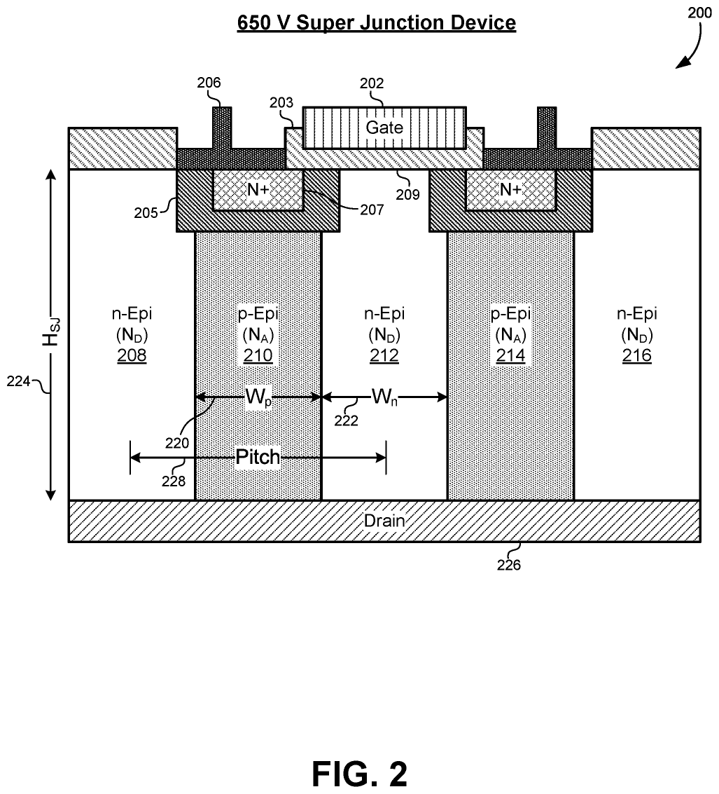

System 100, or more specifically chambers incorporated into system 100 or other processing systems, may be used to produce structures according to some embodiments of the present technology. FIG. 2 illustrates a super junction device 200, according to some embodiments. The device 200 in FIG. 2 is represented by example as a super junction transistor, such as a super junction MOSFET. However, the principles described herein may be used to form any super junction device, and the description is not limited to a super junction transistor.

The device 200 may include a number of different electrical contacts. The device 200 may include a source contact 206 that is electrically coupled to an N+ source region 207 that is formed within a P-well 205. Collectively, the source contact 206, the N+ source region 207, and the P-well 205 may be referred to as a “source region” of the device 200. The device may be formed on a silicon substrate 226. The silicon substrate 226 may form a drain region of the device 200. Although not shown explicitly in FIG. 2, the drain region formed by the substrate 226 may include a conductive contact similar to the source contact 206. The device 200 may also include a gate region that includes a gate contact 202 and a gate oxide 209. Each of the source, drain, and gate regions may include other layers or regions that are not explicitly shown in FIG. 2. Additionally, these contacts may also be referred to in this disclosure more generically as a “first,” “second,” and “third” contact to distinguish one contact from the other in a manner that is not specific to a transistor. For example, in this transistor implementation, the drain region may be referred to as a first contact region, the gate region may be referred to as a second contact region, and the source region may be referred to as a third contact region.

The internal regions of the device 200 may include a plurality of N-doped regions and/or P-doped regions. These regions may also be referred to as “pillars,” as these regions typically extend from the silicon substrate 226 up to the top of the device 200. The device 200 may include a first N-type region 208 that extends orthogonally up from the silicon substrate 226 to the top of the device 200. The device 200 may also include a P-type region 210 that also extends orthogonally up from the silicon substrate 226 to the source region of the device 200. The device 200 may also include a second N-type region 212 that similarly extends orthogonally up from the silicon substrate 226 to the gate region. Note that the device 200 may also include additional contact regions, P-type regions (e.g., P-type region 214), and N-type regions (e.g., N-type region 216), some of which are illustrated in FIG. 2.

Typically, the width 220 of the P-type region 210 and the width 222 of the second N-type region 212 are approximately the same in standard super junction devices. Additionally, a doping level (N_{A}) of the P-type region 210 and a doping level (N_{D}) of the N-type region 212 are also equal. In order to function optimally, the charge should be balance between the second N-type region 212 and the P-type region 210 according to the following equation.

$${N}_{A} {W}_{p} = {N}_{D} {W}_{n} \qquad ( 1 )$$

With careful charge balancing between the N-type pillars in the P-type pillars in the device 200, these regions may completely deplete each other to form a depletion region throughout the bulk of the device 200. Full depletion increases the breakdown voltage of the device 200 significantly without lowering the doping concentrations. This allows the device to have very high doping concentrations in the N-type regions so long as the balance is maintained according to equation (1) above.

The breakdown voltage of the device 200 is also a function of the height 224 of the device 200. Typically, the greater the height 224 of the device 200, the higher the breakdown voltage of the device 200. However, when shrinking the size of the device 200, circuit designers typically focus on reducing the width of the N-type pillars in the P-type pillars. Specifically, the pitch 228 should be reduced to reduce the size of the device 200. A technical problem exists in that manufacturing limitations have limited how much the critical dimension or width of these features can shrink at a given height 224 of the device 200 due to aspect ratios of the features. Specifically, forming the device typically includes forming an N-type material on top of the silicon substrate 226. Trenches are then etched in the N-type region, leaving N-type mesas that include, for example, N-type region 208, N-type region 212, and so forth. The trenches are then filled with the P-type material to form the P-type regions, such as P-type region 210, P-type region 214, and so forth. Therefore, the aspect ratio of the trench limits the width of the trench for a given height.

For example, the device 200 in FIG. 2 may be rated as a 650 V device. The specifications for this 650 V device include a height 224 of about 40 μm. The width 220 of the P-type region 210 is about 2 μm (also referred to as a critical dimension or “CD”). This leads to an aspect ratio of 40/2=20 for a trench that is etched to form the P-type region 210. The pitch 228 is about 4 μm, which may be defined as the distance between centers of consecutive N-type regions. The aspect ratio of 20 has been found to be an acceptable feature size for current etch and fill operations for devices of this size. Increasing the aspect ratio beyond 20 at this size can cause problems when etching the trenches. Specifically, the trenches may erode at the top surface of the trench, and may develop sloped sidewalls with a poorly defined bottom in the trench. Increasing the aspect ratio may also cause problems when filling the trenches. When depositing material in the trenches, the material may close off the trench at the top before the trench is filled throughout the height of the trench. This may cause voids or seams in the P-type regions that interfere with the operation of the device 200.

At high aspect ratios such as 20, special procedures are usually needed in order to ensure that the trench is completely filled. For example, when filling the trenches with P-type epi silicon, the approach usually includes a selective epitaxial fill process in the high aspect ratio trenches. This processes utilizes multiple, alternating growth-and-etch steps to avoid the formation of voids and/or seams. Specifically, a layer of fill material is grown in the trench, then etched back to prevent pinch off and maintain a uniform surface. Performing only a single growth step usually leads to early pinch-off on the top of the trench, thereby blocking the precursor gases from reaching the bottom of the trench for decomposition and epitaxial growth. While this process does produce fully filled trenches, it also takes a considerable amount of time. For example, the high-aspect-ratio trenches described herein may take up to three hours per wafer to complete the fill process. This results in extremely low throughput and severely limits high-volume manufacturing of wafers with super junction devices. Additionally, controlling the defects in the P-type fill material is immensely difficult. If defects are not properly monitored and controlled, these defects can negatively impact the device characteristics by increasing the leakage current and decreasing the breakdown voltage. Therefore, numerous technical problems exist with current super junction device manufacturing.

The embodiments described herein solve this problem of creating a high-voltage device by using a liner to create the P-type regions instead of etching and filling the trench with P-type material. The trench is lined with the P-type liner and may then be filled with a passive fill material, such as an undoped silicon material. The passive fill material may be deposited or grown relatively quickly in the trench, and voids or seams may form. However the passive fill material does not affect the operation of the device, so these voids or seams are acceptable. Since the trenches did not need to be carefully and completely filled, the aspect ratio of the trenches may increase. For example, the width of the trenches may decrease, which in turn decreases the pitch and the size of the device.

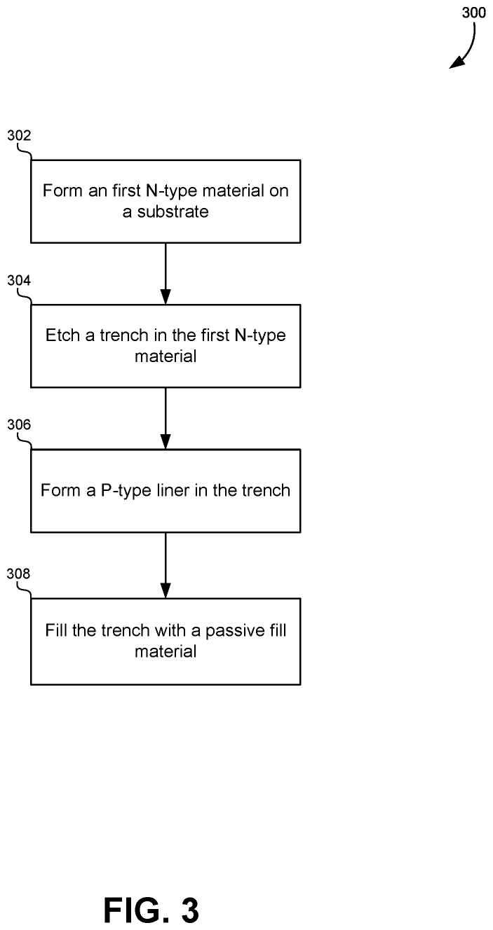

FIG. 3 illustrates a flowchart 300 of a method of forming a super junction device that allows for a reduced pitch and faster trench fill, according to some embodiments. The method of flowchart 300 may be performed in one or more processing chambers, such as chambers incorporated in the system 100 described above. The method of flowchart 300 may or may not include one or more operations prior to the initiation of the method, including front-end processing, deposition, etching, polishing, cleaning, or any other operations that may be performed prior to the described operations. The method may also include a number of optional operations as denoted in the figure, which may or may not be specifically associated with some embodiments of methods according to the present technology.

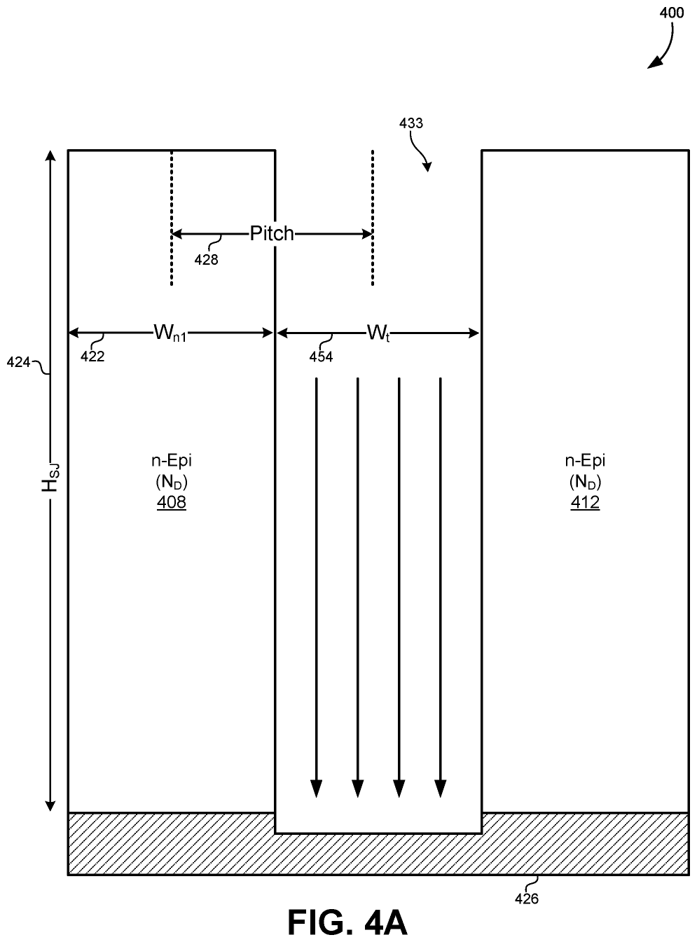

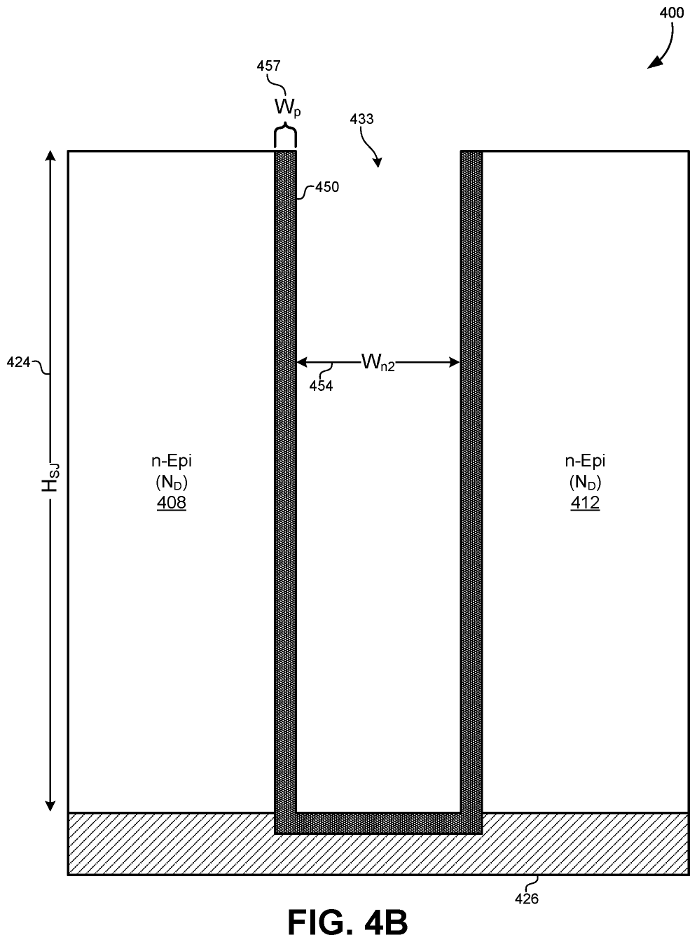

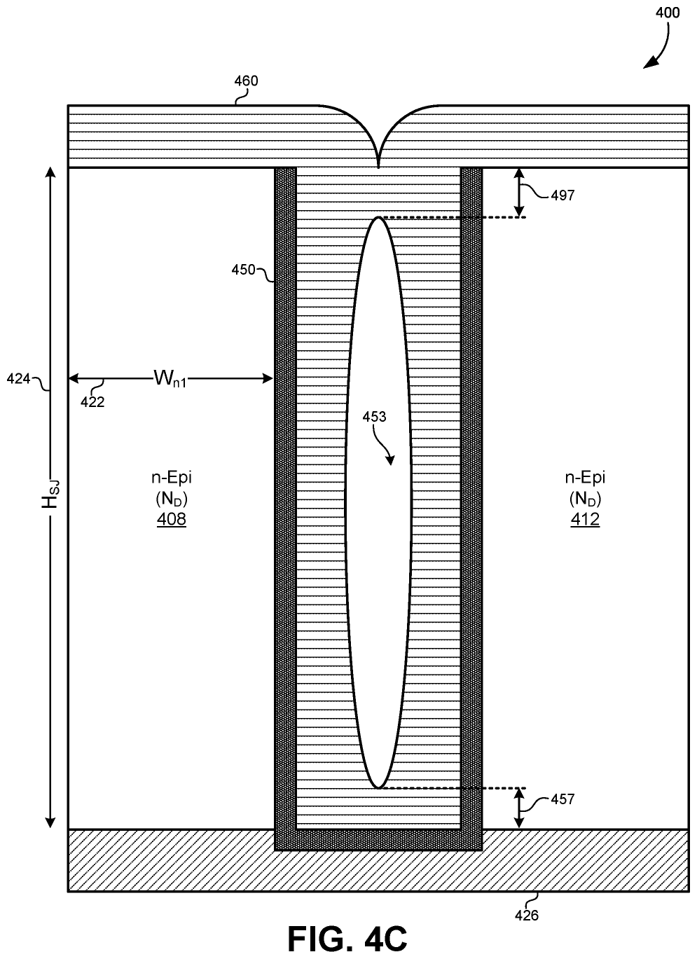

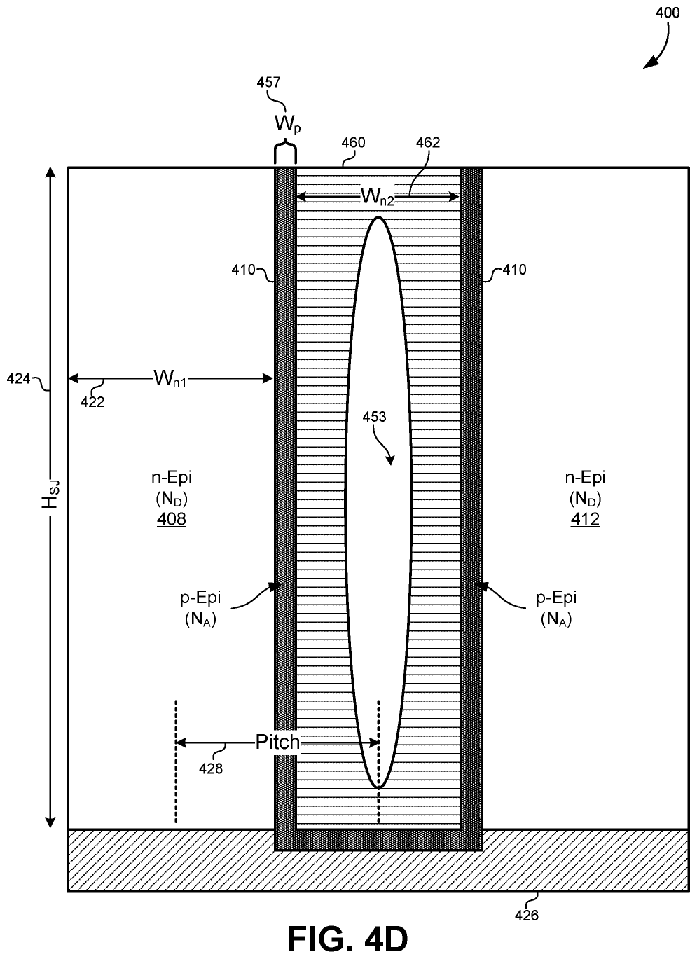

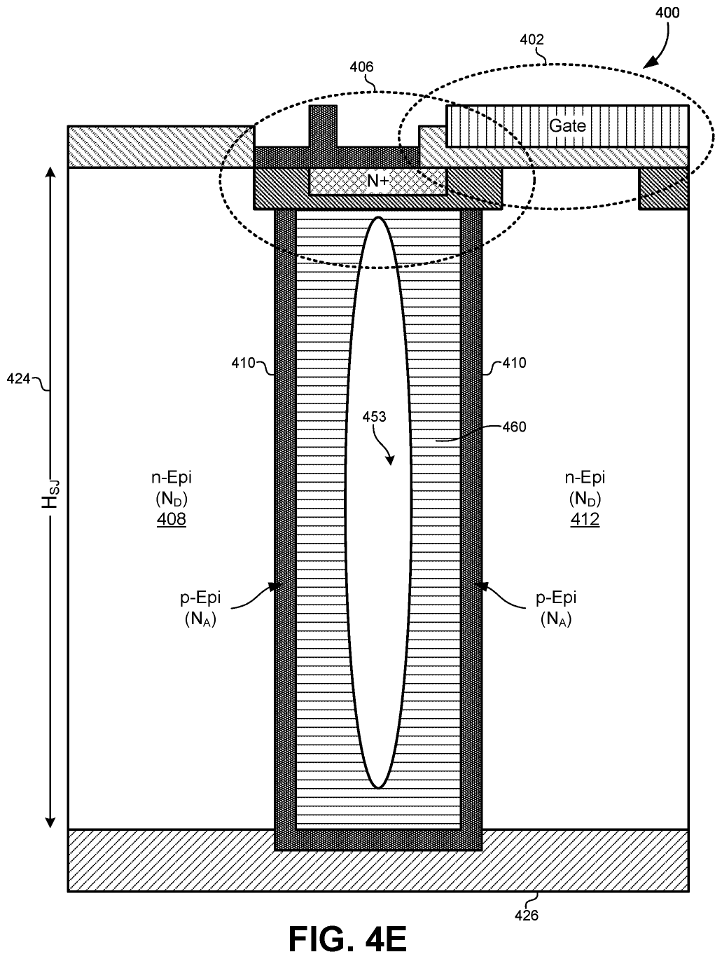

FIGS. 4A-4E illustrate incremental structures for forming the super junction device, according to some embodiments. The method of flowchart 300 describes operations shown schematically in FIGS. 4A-4E, the illustrations of which will be described in conjunction with the operations of this method. It is to be understood that the figures illustrate only partial schematic views with limited details, and in some embodiments a substrate may contain any number of semiconductor sections having aspects as illustrated in the figures, as well as alternative structural aspects that may still benefit from any of the aspects of the present technology.

The method of flowchart 300 may include forming a first N-type region over a substrate (302). As illustrated in FIG. 4A, the structure 400 may include a substrate 426. The substrate 426 may have a substantially planar surface or an uneven surface in various embodiments. The substrate 426 may be a material such as crystalline silicon, silicon oxide, strained silicon, silicon germanium, doped or undoped polysilicon, doped or undoped silicon wafers, patterned or non-patterned wafers, silicon on insulator, carbon doped silicon oxides, silicon nitride, doped silicon, germanium, gallium arsenide, or sapphire. As one non-limiting example, in some embodiments the substrate may be or include an N+ material, such as N+ silicon. The substrate 426 may have various dimensions, such as 200 mm or 300 mm diameter wafers, as well as rectangular or square panels. The substrate 426 may be disposed within the processing region of the semiconductor processing chamber. Although shown as a planar substrate, it is to be understood that substrate 426 is included merely to represent an underlying structure, which may include any number of layers or features on a wafer or other substrate, and over which structures as described below may be formed.

Above the substrate 426, the structure 400 may include a first N-type material. The first N-type material may be disposed along at least a portion or all of the substrate 426. The first N-type material may be N-type silicon, and which may be doped with phosphorous, arsenic, a combination of both, or other similar materials. The first N-type material may form the first N-type region 408 and the second N-type region 412, although the mesa or pillar of these regions (and possibly other N-type regions) may not become apparent until after one or more trenches are etched in the following operation. The height of the first N-type material and the eventual first N-type region 408 may be greater than or about 20 μm, between about 20 μm and about 30 μm, between about 30 μm and about 40 μm, between about 40 μm and about 50 μm, between about 50 μm and about 60 μm, between about 60 μm and about 70 μm, between about 70 μm and about 80 μm, greater than or about 80 μm, greater than or about 90 μm, and so forth.

In some embodiments, to facilitate patterning of the first N-type material, hard masks, photoresists, or any other mask materials may be disposed along the first N-type material. For example a first mask may be formed over the first N-type material, and a second mask may be formed over the first mask. In some embodiments, either or both masks may be any number of materials to promote structural formation, such as oxides, nitrides, carbides, or some combination of materials. For example, the first mask may be or include silicon nitride, and the second mask may be or include silicon oxide, or some other mask material. It is contemplated that a singular mask may be provided over the first N-type material and the embodiment depicted in FIG. 4A is merely one example structure 400.

The method of flowchart 300 may also include etching a trench 433 in the first N-type material (304). As shown in FIG. 4A, a pattern may be etched or formed through the first mask and/or the second mask to form features, such as the trench 433. The trench 433 may be etched through the first mask and/or the second mask using any etching processes and any etching reagents. In some embodiments, the etching may completely remove the second mask as a pattern is transferred into the underlying N-type material.

The etching of the first N-type material may form one or more trenches in the material. The trench 433 may be formed to a depth of greater than or about 10 μm, greater than or about 15 μm, greater than or about 20 μm, greater than or about 25 μm, greater than or about 30 μm, greater than or about 35 μm, greater than or about 40 μm, greater than or about 45 μm, greater than or about 50 μm, greater than or about 55 μm, greater than or about 60 μm, greater than or about 65 μm, greater than or about 70 μm, greater than or about 75 μm, greater than or about 80 μm, greater than or about 85 μm, greater than or about 90 μm, greater than or about 95 μm, greater than or about 100 μm, or greater. As illustrated in FIG. 4A, the trench 433 may extend all the way down to a top surface of the substrate 426. In some embodiments, the trench 433 may extend below a top surface of the substrate 426 such that the trench 433 penetrates the substrate 426. As described below, this provides a surface from which epitaxial silicon may be grown from the substrate 426 when filling the trench 433. This also allows the P-type liner to electrically contact the substrate 426. Therefore, the height of the trench 433 correspond to any of the heights described above for the first N-type region 408 or higher. For example, the trench 433 may be about 40 μm high or slightly higher when extending into the substrate 426 for a 650 V device.

The trench 433 may have an aspect ratio, or a depth-to-width ratio less than or about 50, less than or about 40, less than or about 30, less than or about 25, less than or about 20, less than or about 15, less than or about 10, or less. As described above, this procedure allows the trench to be etched to a smaller width 454 for a given height 424. This in turn increases the aspect ratio and decreases the pitch 428. For example, the current pitch 428 of standard 650 V devices is about 7 μm, resulting in a width 454 for the trench 433 of about 3.5 μm. The embodiments described herein may reduce the pitch 428 to be less than or about 6 μm, less than or about 5 μm, less than or about 4 μm, less than or about 3 μm, or less than or about 2 μm. A trench 433 with a width 454 as small 1 micron μm would not be possible without the methods described herein for a 650 V device with a height of about 40 μm or more.

The method of flowchart 300 may include forming a P-type liner 450 in the trench 433 (306). FIG. 4B illustrates forming a P-type liner 450 in the trench 433, according to some embodiments. The deposition or formation may be performed in any number of ways, and in some embodiments the material may be formed conformally about the trench feature. The P-type liner 450, which may be p-type silicon, for example, may be deposited by atomic layer deposition, grown epitaxially, or produced by any number of other processes to produce conformal coverage about the trench 433. The P-type liner 450 may be characterized by a thickness of between about 50 nm and about 100 nm, between about 100 nm and about 150 nm, between about 150 nm and about 200 nm, between about 200 nm and about 250 nm, between about 250 nm and about 300 nm, greater than or about 300 nm, and so forth. The P-type liner 450 may also be characterized by a thickness of less than or about 200 nm, less than or about 150 nm, less than or about 100 nm, less than or about 90 nm, less than or about 80 nm, less than or about 70 nm, less than or about 60 nm, less than or about 50 nm, less than or about 40 nm, less than or about 30 nm, less than or about 20 nm, less than or about 10 nm, less than or about 5 nm, or less. The P-type liner 450 may be a silicon-containing material doped with boron or other similar materials. In some embodiments, the P-type liner 450 may also include germanium.

The P-type liner 450 may substantially cover the sidewall portion of the first N-type region 408 in the trench 433. In some embodiments, the P-type liner 450 may also be formed on the bottom of the trench 433. The P-type liner 450 may be free of seams and/or voids based on the conformal coverage about the structure, even to a depth of several hundred nanometers, which may provide large improvements on performance for final devices compared to conventional technologies that have reduced or incomplete coverage at greater depths, as well as seam or void formation. However, it is contemplated that some pores may be present in the P-type liner 450, depending on the formation and thickness.

The method of flowchart 300 may further include filling the trench 433 with a passive fill material (308). FIG. 4C illustrates the formation of the passive fill material 460, according to some embodiments. The passive fill material 460 may fill the trench 433 by backfilling the internal region of the trench 433 between the sidewalls on which the P-type liner 450 has been formed. In some embodiments, the passive fill material 460 may be formed as a single-step process. For example, the passive fill material 460 may be formed without using the one or more grow-etch cycles described above that are typically used to evenly fill the trench 433. This single-step process may fill the trench 433 with the passive fill material 460 in less than or about 15 minutes, or less than about 20 minutes, depending on the process.

Various materials may be used for the passive fill material 460. For example, the passive fill material 460 may include undoped silicon that is electrically neutral in comparison to the N-doped silicon and/or the P-doped silicon used elsewhere in the structure 400. Other similar materials may also be used. The P-type liner 450 may surround the passive fill material 460 in the trench 433.

In some embodiments, the passive fill material 460 may be quickly formed by using a relatively high temperature to reduce the processing time. For example, the temperature while forming the passive fill material 460 may be raised to greater than or about 750°, greater than or about 800°, greater than or about 850°, greater than or about 900°, greater than or about 950°, greater than or about 1000°, and so forth.

While typically avoided, these embodiments allow for the formation of a void or seam, such as the void 438 illustrated in FIG. 4C. The void 453 may be allowed in this instance since the passive fill material 460 is electrically neutral in the structure 400. Therefore, the void 453 may be tolerated without affecting the performance of the structure 400. In some embodiments, the void 453 may be allowed with a distance 497 of at least 1 μm from a top of the structure 400, and/or a distance 458 of at least 1 μm from a bottom of the trench 433 or a top of the substrate 426.

Additional operations may include removing a portion of the passive fill material 460 and any remaining mask material by planarizing the structure, such as with a chemical-mechanical polishing operation. FIG. 4D illustrates a planarized structure with a fill the trench, according to some embodiments. At this stage, the P-type liner 450 may alternatively be referred to as a P-type region 410 since it is ready to perform that function in the structure 400. The pitch 428 may be as small as 2 μm, with the width 422 of the first N-type region 408 being about 1 μm, the width 457 of the P-type region 410 being about 200 nm, and a width 462 of the passive fill material 460 being about 800 nm. Note that FIG. 4D is not drawn to scale.

The doping level of the first N-type region 408 may remain the same as for the 650 V device in FIG. 2. For example, the doping level of the first N-type region 408 may be between about 1e14 dopants/cm³ and about 1e16 dopants/cm³ (e.g., 7e15 dopants/cm³ in some embodiments). The doping level of the P-type region 410 may be greater than or about 8 times, greater than or about 9 times, greater than or about 10 times, and so forth, of the doping level of the first N-type region 408. Specifically, the doping level of the P-type region 410 may be increased to balance equation (1) above such that the product of the doping level of the first N-type region 408 and the width 422 of the first N-type region 408 is equal to the product of the doping level of the P-type region 410 and the width 457 of the P-type region 410 (i.e., the thickness of the P-type liner 450).

Additional operations may include forming the remaining contact regions for the structure 400. FIG. 4E illustrates the structure 400 with contact regions, according to some embodiments. The structure 400 may include a gate region 402 and/or a source region 406 to complement a drain region formed by the substrate 426. The first N-type region 408 may extend orthogonally up from the substrate 426, or drain region. A second N-type region 412 may also extend orthogonally up from the substrate 426 to a gate region 402 of the structure 400. A trench between the first N-type region 408 and the second N-type region 412 may be lined with the P-type liner 450 along the sidewalls of the trench to form the P-type region 410. The P-type region 410 may contact the drain formed by the substrate 426 and may extend up to contact the source region 406 of the device. The passive fill material 460 may also extend up to the source region 406. The structure 400 may include the void 453 in the passive fill material 460 after the structure 400 is completed.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a pillar” includes a plurality of such pillars, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMs, EPROMS, EEPROMs, magnetic or optical cards, flash memory, or other types of machine-readable mediums suitable for storing electronic instructions. Alternatively, the methods may be performed by a combination of hardware and software.

What is claimed is:

1. A super junction device comprising:
a first N-type region extending orthogonally up from a substrate, wherein the substrate forms a first contact region for the device;
a second N-type region extending orthogonally up from the substrate to a second contact region of the device; and
a trench between the first N-type region and the second N-type region, wherein the trench is lined with a P-type liner along sidewalls of the trench, the P-type liner contacts a third contact region of the device, and the trench is filled with a passive fill material between the P-type liner.

2. The super junction device of claim 1, wherein a height of the P-type liner is greater than or about 40 μm.

3. The super junction device of claim 1, wherein a width of the P-type liner is less than or about 200 nm.

4. The super junction device of claim 1, wherein:
the first contact region comprises a drain of a super junction transistor;
the second contact region comprises a gate of the super junction transistor; and
the third contact region comprises a source of the super junction transistor.

5. The super junction device of claim 4, wherein the super junction transistor has a breakdown voltage of greater than or about 650 V.

6. The super junction device of claim 1, wherein a width of the trench is less than or about 2 μm.

7. The super junction device of claim 1, wherein a doping concentration of the P-type liner is higher than a doping concentration of the second N-type region.

8. A super junction device comprising:
a silicon substrate forming a drain region for the device;
a gate region;
a source region;
an N-type region extending from the silicon substrate up to the gate region;
a P-type region extending from the silicon substrate up to the source region; and
a passive fill material extending up to the source region, wherein the P-type region is between the passive fill material and the N-type region, and the passive fill material comprises a void or seam inside the passive fill material.

9. The super junction device of claim 8, wherein the void or seam is a least 1 μm from a bottom of the passive fill material, and the void or seam is at least 1 μm from a top of the passive fill material.

10. The super junction device of claim 8, wherein an aspect ratio of an area occupied by the P-type region and the passive fill material is greater than or about 20.

11. The super junction device of claim 8, wherein an aspect ratio of an area occupied by the P-type region and the passive fill material is greater than or about 40.

12. A method of forming a super junction device, the method comprising:
forming an N-type material on a substrate;
etching a trench in the N-type material, wherein the trench extends from a top surface of the N-type material down to at least a top surface of the substrate to form a first N-type region and a second N-type region;
forming a P-type liner in the trench; and
filling the trench with a passive fill material.

13. The method of claim 12, wherein the trench is filled with the passive fill material in less than 15 minutes.

14. The method of claim 12, wherein the trench is filled with the passive fill material without one or more grow-etch cycles.

15. The method of claim 12, wherein the passive fill material comprises undoped silicon.

16. The method of claim 12, wherein the trench is filled with the passive fill material at a temperature greater than or about 900° C.

17. The method of claim 12, further comprising planarizing a top surface of the device after filling the trench with the passive fill material to remove excess passive fill material.

18. The method of claim 12, wherein the trench is etched below the top surface of the substrate.

19. The method of claim 12, wherein the P-type liner is grown on sidewalls of the trench as a P-doped epitaxial silicon liner.

20. The method of claim 12, wherein a doping concentration of the N-type material is between about 1e14 dopants/cm³ and about 1e16 dopants/cm³, and a doping concentration of the P-type liner is greater than about 8 times the doping concentration of the N-type material.
